(19) United States
(12) Patent Application Publication
(10) Pub. No.: US 2023/0212382 A1
(43) Pub. Date: Jul. 6, 2023

(54) DISPLAY DEVICE

(71) Applicant: LG DISPLAY CO., LTD., SEOUL (KR)

(72) Inventors: SeongYong UHM, Gyeonggi-do (KR); KyuNam KIM, Gyeonggi-do (KR); Dohyung KIM, Gyeonggi-do (KR); MinHo OH, Seoul (KR)

(73) Assignee: LG DISPLAY CO., LTD., SEOUL (KR)

(21) Appl. No.: 17/985,954

(22) Filed: Nov. 14, 2022

(30) Foreign Application Priority Data
Dec. 30, 2021 (KR) 10-2021-0193494

(51) Int. Cl. C08L 33/10

(52) U.S. Cl. CPC C08L 33/10; H01L 51/5237; C08L 2203/206

(57) ABSTRACT

A display device includes a substrate, a light-emitting element positioned on the substrate; and an encapsulation layer positioned on the light-emitting element and comprising a first layer, a second layer positioned on the first layer, and a third layer positioned on the second layer, wherein the first layer comprises a first polymer, the second layer comprises a compound represented by Formula 1, and the third layer comprises a second polymer and a hygroscopic getter, wherein, in Formula 1, A is a C₁-C₁₀ alkyl group or a C₆-C₆₀ aryl group, n is an integer from 1 to 100, m is an integer from 1 to 6, o is an integer greater than or equal to 1, and R¹ is a hydroxyl group.

### CROSS REFERENCE TO RELATED APPLICATION

This application claims the priority of Korean Patent Application No. 10-2021-0193494, filed on Dec. 30, 2021, which is hereby incorporated by reference in its entirety.

### BACKGROUND

### Field of the Disclosure

The present disclosure relates to a display device.

### Description of the Background

A display device may include a plurality of pixels including light-emitting elements and various circuit elements for driving the light-emitting elements. There is a problem in that some of light-emitting elements and various circuit elements included in a display device are vulnerable to moisture and oxygen.

In order for a display device to have excellent durability, it is required to isolate light-emitting elements and circuit elements included in the display device from external moisture and oxygen. Sealing a light-emitting element included in a display device in order to isolate the light-emitting element from external moisture and oxygen is referred to as encapsulation, and various technologies related to the encapsulation are being researched.

Light-emitting elements and various circuit elements for driving the light-emitting element may be disposed in a display device. In particular, in a non-display area that is an edge of a display panel included in the display device, a pad portion for connection to a driving circuit for driving the various circuit elements may be present.

A glass or metal may be used for a front surface of the display panel to block external moisture and oxygen, but in consideration of the shape of the display device, it is difficult to use a glass or metal for a side surface of the display panel. When the side surface is sealed using a polymer or an adhesive film, since external moisture and oxygen is easily introduced through the side surface, a sufficient distance has been needed to prevent the introduction of moisture and oxygen for a long time.

However, when a sufficient distance is secured between the side surface of the display panel and the circuit elements such as the light-emitting elements of the display panel to prevent the introduction of moisture and oxygen, there has been a problem in that a bezel area of the display device is widened.

### SUMMARY

Accordingly, the present disclosure is to provide a display device including an encapsulation layer capable of easily protecting a light-emitting element or the like of the display device from oxygen and moisture introduced from a side surface.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

In an aspect of the present disclosure, a display device includes a substrate, a light-emitting element positioned on the substrate, and an encapsulation layer positioned on the light-emitting element, the encapsulation layer may include a first layer, a second layer positioned on the first layer, and a third layer positioned on the second layer, wherein the first layer may include a first polymer and the third layer may include a second polymer and a hygroscopic getter.

The second layer may include a compound represented by Formula 1 below.

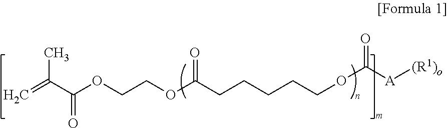

According to aspects of the present disclosure, a display device can have excellent reliability because the display device includes an encapsulation layer including a second layer represented by Formula 1.

It is to be understood that both the foregoing general description and the following detailed description are exemplary and explanatory and are intended to provide further explanation of the disclosure as claimed.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a system configuration diagram of a display device according to aspects of the present disclosure;

FIG. 2 is a configuration diagram of a display area in which a light-emitting element of a display device is positioned according to aspects of the present disclosure;

FIG. 3 is a cross-sectional view of a non-display area and a display area of a display device according to aspects of the present disclosure;

FIG. 4 is a cross-sectional view of a display device according to a comparative example of the present disclosure;

FIG. 5 is a cross-sectional view of a display device according to aspects of the present disclosure; and

FIG. 6 shows results of measuring oxygen permeation according to a time change in Examples and Comparative Examples of the present disclosure.

### DETAILED DESCRIPTION

In the following description of examples or aspects of the present disclosure, reference will be made to the accompanying drawings in which it is shown by way of illustration specific examples or aspects that can be implemented, and in which the same reference numerals and signs can be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Unless otherwise stated, in the present disclosure, the term “alkyl group” may have 1 to 60 carbon atoms that are single-bonded and may be a saturated aliphatic functional radical including a straight chain alkyl group, a branched chain alkyl group, a cycloalkyl (alicyclic) group, an alkyl-substituted cycloalkyl group, or a cycloalkyl-substituted alkyl group.

Unless otherwise stated, the term “aryl group” used in the present disclosure has 6 to 60 carbon atoms, but the present disclosure is not limited thereto. In the present disclosure, the aryl group may include a monocyclic compound, a ring assembly, fused polycyclic systems, a spiro compound, or the like. For example, the aryl group may include a phenyl group, biphenyl, naphthyl, anthryl, indenyl, phenanthryl, triphenylenyl, pyrenyl, peryleneyl, chrysenyl, naphthacenyl, fluoranthenyl, and the like, but the present disclosure is not limited thereto. The naphthyl may include 1-naphthyl and 2-naphthyl, and the anthryl may include 1-anthryl, 2-anthryl, and 9-anthryl.

Hereinafter, various aspects of the present disclosure will be described in detail with reference to the accompanying drawings.

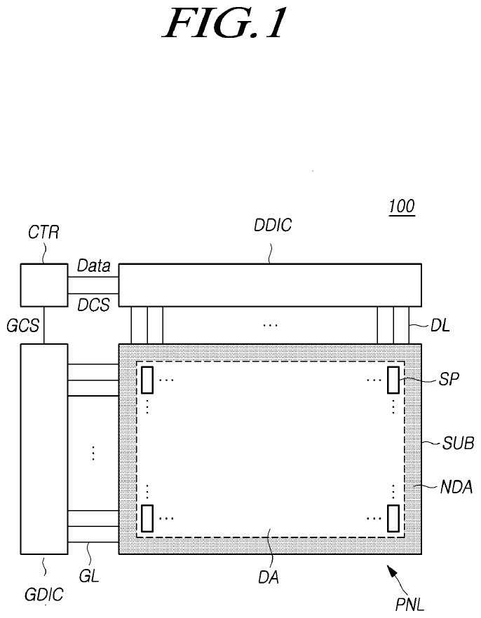

FIG. 1 is a system configuration diagram of a display device 100 according to aspects of the present disclosure.

Referring to FIG. 1, the display device 100 according to aspects of the present disclosure may include a display panel PNL and a driving circuit for driving the display panel PNL.

The driving circuit may include a data driving circuit DDIC and a gate driving circuit GDIC and may further include a controller CTR for controlling the data driving circuit DDIC and the gate driving circuit GDIC.

The display panel PNL may include a substrate SUB and signal lines such as a plurality of data lines DL and a plurality of gate lines GL disposed on the substrate SUB. The display panel PNL may include a plurality of subpixels SP connected to the plurality of data lines DL and the plurality of gate lines GL.

The display panel PNL may include a display area DA in which an image is displayed and a non-display area NDA in which an image is not displayed. In the display panel PNL, the plurality of subpixels SP for displaying an image may be disposed in the display area DA, and in the non-display area NDA, the driving circuits DDIC and GDIC, and the controller CTR may be electrically connected or mounted, and a pad portion to which an integrated circuit (IC) or a printed circuit is connected may also be disposed.

The data driving circuit DDIC may be a circuit for driving the plurality of data lines DL and may supply data signals to the plurality of data lines DL. The gate driving circuit GDIC may be a circuit for driving the plurality of gate lines GL and may supply gate signals to the plurality of gate lines GL. The controller CTR may supply a data control signal DCS to the data driving circuit DDIC to control an operation timing of the data driving circuit DDIC. The controller CTR may supply a gate control signal GCS to the gate driving circuit GDIC to control an operation timing of the gate driving circuit GDIC.

The controller CTR may start a scan according to a timing implemented in each frame. The controller CTR may convert input image data input from an external device to be suitable for a data signal format used by the data driving circuit DDIC, may supply the converted image data to the data driving circuit DDIC, and may control data driving at an appropriate time according to the scan.

In order to control the gate driving circuit GDIC, the controller CTR may output various gate control signals GCS including gate start pulse (GSP), gate shift clock (GSC), and gate output enable (GOE) signals.

In order to control the data driving circuit DDIC, the controller CTR may output various data control signals DCS including source start pulse (SSP), source sampling clock (SSC), and source output enable (SOE) signals.

The controller CTR may be implemented as a separate component from the data driving circuit DDIC or may be integrated with the data driving circuit DDIC and implemented as an integrated circuit (IC).

The data driving circuit DDIC receives image data DATA from the controller CTR and supplies data voltages to the plurality of data lines DL to drive the plurality of data lines DL. Here, the data driving circuit DDIC is also referred to as a source driving circuit.

The data driving circuit DDIC may include one or more source driver integrated circuits (SDICs).

For example, each SDIC may be connected to the display panel PNL as a tape automated bonding (TAB) type, may be connected to a bonding pad of the display panel PNL as a chip-on-glass (COG) or chip-on-panel (COP) type, or may be implemented as a chip-on-film (COF) type and connected to the display panel PNL.

The gate driving circuit GDIC may output a gate signal having a turn-on level voltage or a gate signal having a turn-off level voltage under the control of the controller CTR. The gate driving circuit GDIC may sequentially drive the plurality of gate lines GL by sequentially supplying a gate signal having a turn-on level voltage to the plurality of gate lines GL.

The gate driving circuit GDIC may be connected to the display panel PNL as a TAB type, may be connected to a bonding pad of the display panel PNL as a COG or COP type, or may be connected to the display panel PNL as a COF type. Alternatively, the gate driving circuit GDIC may be formed in the non-display area NDA of the display panel PNL as a gate-in-panel (GIP) type. The gate driving circuit GDIC may be disposed on or connected to the substrate SUB. That is, when the gate driving circuit GDIC is the GIP type, the gate driving circuit GDIC may be disposed in the non-display area NDA of the substrate SUB. When the gate driving circuit GDIC is the COG type, the COF type, or the like, the gate driving circuit GDIC may be connected to the substrate SUB.

Meanwhile, at least one driving circuit of the data driving circuit DDIC and the gate driving circuit GDIC may be disposed in the display area DA. For example, at least one driving circuit of at least one of the data driving circuit DDIC and the gate driving circuit GDIC may be disposed to not overlap the subpixels SP or may be disposed such that a portion or the entirety thereof overlaps the subpixels SP.

When a specific gate line GL is opened by the gate driving circuit GDIC, the data driving circuit DDIC may convert the image data DATA received from the controller CTR into an analog data voltage and may supply the analog data voltage to the plurality of data lines DL.

The data driving circuit DDIC may be connected to one side (for example, an upper or lower side) of the display panel PNL. According to a driving method, a panel design method, or the like, the data driving circuit DDIC may be connected to two sides (for example, the upper and lower sides) of the display panel PNL or may be connected to two or more sides of the four sides of the display panel PNL.

The gate driving circuit GDIC may be connected to one side (for example, a left side or a right side) of the display panel PNL. According to a driving method, a panel design method, or the like, the gate driving circuit GDIC may be connected to two sides (for example, the left and right sides) of the display panel PNL or may be connected to two or more sides of the four sides of the display panel PNL.

The controller CTR may be a timing controller used in typical display technology, may be a control device which may include the timing controller to further perform other control functions, may be a control device different from the timing controller, or may be a circuit inside a control device. The controller CTR may be implemented with various circuits or electronic components such as an IC, a field programmable gate array (FPGA), an application specific integrated circuit (ASIC), and a processor.

The controller CTR may be mounted on a printed circuit board, a flexible printed circuit, or the like and may be electrically connected to the data driving circuit DDIC and the gate driving circuit GDIC through the printed circuit board or the flexible printed circuit.

The display device 100 according to the present aspects may be a display including a backlight unit such as a liquid crystal display or may be a self-luminous display such as an organic light-emitting diode (OLED) display, a quantum dot display, or a micro light-emitting diode (micro LED) display.

When the display device 100 according to the present aspects is the OLED display, each subpixel SP may include an OLED, which emits light by itself, as a light-emitting element. When the display device 100 according to the present aspects is the quantum dot display, each subpixel SP may include a light-emitting element made of quantum dots which are a semiconductor crystal that emits light by itself. When the display device 100 according to the present aspects is the micro LED display, each subpixel SP may include a micro LED, which emits light by itself and is made based on an inorganic material, as a light-emitting element.

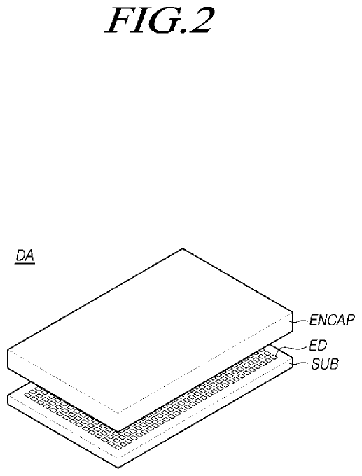

FIG. 2 is a configuration diagram of a display area in which a light-emitting element of a display device is positioned according to aspects of the present disclosure.

Referring to FIG. 2, the display device may include a substrate SUB, a plurality of light-emitting elements ED disposed on the substrate SUB, and an encapsulation layer ENCAP disposed on the light-emitting elements ED.

In a display area DA, the plurality of light-emitting elements ED may be positioned on the substrate SUB. Since the plurality of light-emitting elements ED are positioned in the display area DA, an image may be displayed in the display area DA.

The encapsulation layer ENCAP for protecting the light-emitting elements ED may be disposed on the light-emitting elements ED.

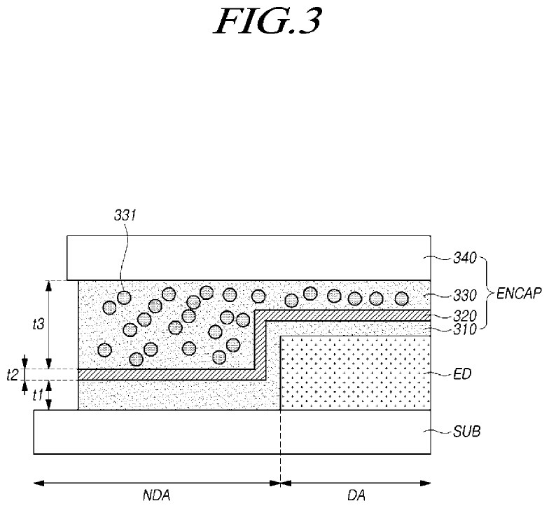

FIG. 3 is a cross-sectional view of a non-display area and a display area of a display device according to aspects of the present disclosure.

Referring to FIG. 3, the display device may include a substrate SUB, light-emitting elements ED disposed on the substrate, and an encapsulation layer ENCAP disposed on the light-emitting elements ED.

The substrate SUB may include a display area DA and a non-display area NDA. The plurality of light-emitting elements ED may be positioned in the display area DA. In the non-display area NDA, the light-emitting element ED is not positioned, and various circuit elements for driving the light-emitting element ED may be mounted or a pad portion for connection with the circuit elements may be positioned.

The light-emitting elements ED may be positioned on the substrate.

The encapsulation layer ENCAP may be disposed on the light-emitting elements ED. The encapsulation layer ENCAP may include a first layer 310, a second layer 320, and a third layer 330. The first layer 310 may be disposed on the substrate SUB and the light-emitting elements ED. The second layer 320 may be positioned on the first layer 310. The third layer 330 may be positioned on the second layer 320.

The first layer 310 may include a first polymer. The third layer 330 may include a second polymer and a hygroscopic getter 331.

The first polymer may be a polymer used to encapsulate the light-emitting element ED in the technical field of the present disclosure. For example, the first polymer may be polyisobutylene.

A weight average molecular weight of the first polymer may be in a range of 200,000 to 800,000, 300,000 to 600,000, or 350,000 to 500,000. When the weight average molecular weight of the first polymer satisfies the above range, the encapsulation layer ENCAP may have excellent adhesion and durability.

The second polymer may be a polymer used to encapsulate the light-emitting element ED in the technical field of the present disclosure. For example, the second polymer may be polyisobutylene.

A weight average molecular weight of the second polymer may be in a range of 200,000 to 800,000, 300,000 to 600,000, or 350,000 to 500,000. When the weight average molecular weight of the second polymer satisfies the above range, the encapsulation layer ENCAP may have excellent adhesion and durability.

The first polymer and the second polymer may be substantially the same polymer. The substantially same polymer may mean that the first polymer and the second polymer are polymers including the same repeating unit and have substantially the same weight average molecular weight.

A type of the hygroscopic getter 331 is not particularly limited as long as the hygroscopic getter 331 may be used as a hygroscopic getter for the encapsulation layer ENCAP in the technical field of the present disclosure. For example, the hygroscopic getter may include CaO.

Since the third layer 330 includes the hygroscopic getter, the third layer 330 may have excellent moisture barrier properties.

The second layer 320 may include a compound represented by Formula 1 below.

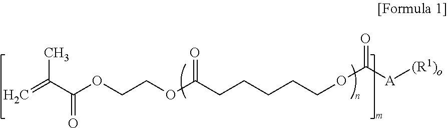

In Formula 1, A is a C₁-C₁₀ alkyl group or a C₆-C₆₀ aryl group.

n may be an integer from 1 to 100. When n satisfies the above range, the compound represented by Formula 1 may have excellent solubility, and a molar fraction of R¹, which is a functional group, may have an appropriate value to have excellent oxygen barrier properties.

m may be an integer from 1 to 6. When m exceeds 6, curls or cracks may be generated in the encapsulation layer, which degrades the external oxygen blocking performance of the encapsulation layer.

o may be an integer that is greater than or equal to 1.

R¹ may be a hydroxyl group.

Since the second layer 320 includes the compound represented by Formula 1 above, the second layer 320 may have a property of blocking oxygen as well as a property of transmitting moisture. Accordingly, moisture introduced through the non-display area NDA of the display device can be removed by the hygroscopic getter 331 included in the third layer 330, and oxygen can be blocked from reaching the light-emitting element ED.

The compound represented by Formula 1 may be represented by any one of Formulas 2 to 7 below.

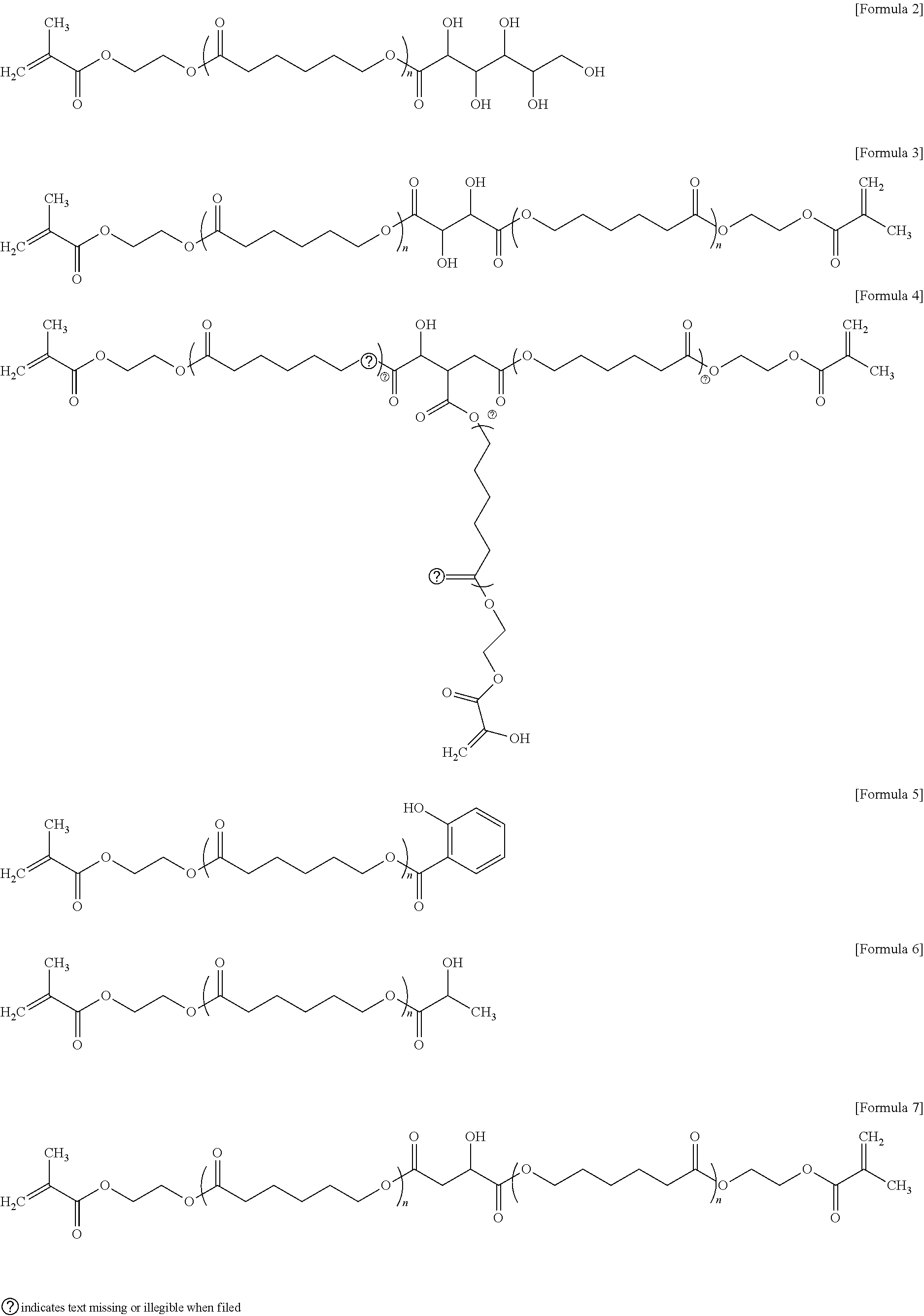

In Formulas 1 to 7, n may be an integer from 1 to 100.

Since the encapsulation layer ENCAP includes the first layer 310, the second layer 320, and the third layer 330, the encapsulation layer ENCAP may have excellent moisture and oxygen barrier properties.

The first layer 310 may allow the encapsulation layer ENCAP to have excellent adhesion. Since the third layer 330 includes the hygroscopic getter 331, the third layer 330 can prevent moisture from penetrating into the light-emitting element ED. The second layer 320 may be positioned between the first layer 310 and the third layer 330 and may have a property of blocking oxygen and a property of transmitting moisture. That is, the second layer 320 may have selective permeability with respect to oxygen and moisture. The selective permeability of the second layer 320 may be obtained by including the above-described polymer represented by Formula 1.

A thickness t1 of the first layer 310 may be in a range of 5 μm to 20 μm, a thickness t2 of the second layer 320 may be in a range of 1 μm to 30 μm, and a thickness t3 of the third layer 330 may be in a range of 10 μm to 80 μm. Each of the thicknesses t1, t2, and t3 may be a thickness measured in the non-display area NDA and may be a thickness observed in a micrograph of the non-display area NDA.

When the second layer 320 has the above-described thickness, pinholes can be prevented from being generated in an upper portion of the first layer 310, and moisture introduced from a side surface of the display device can be easily absorbed by the hygroscopic getter 331 of the third layer 330.

The encapsulation layer ENCAP may include an encapsulation substrate 340. The encapsulation substrate 340 may be a glass, a metal, a polymer film. For example, after the third layer 330, the second layer 320, and the first layer 310 are formed on the encapsulation substrate 340, the encapsulation substrate 340 is laminated with the substrate SUB on which the light-emitting element ED is positioned, thereby manufacturing a display device.

When the encapsulation substrate 340 is made of a metal, the encapsulation substrate 340 may have excellent moisture barrier properties and oxygen barrier properties.

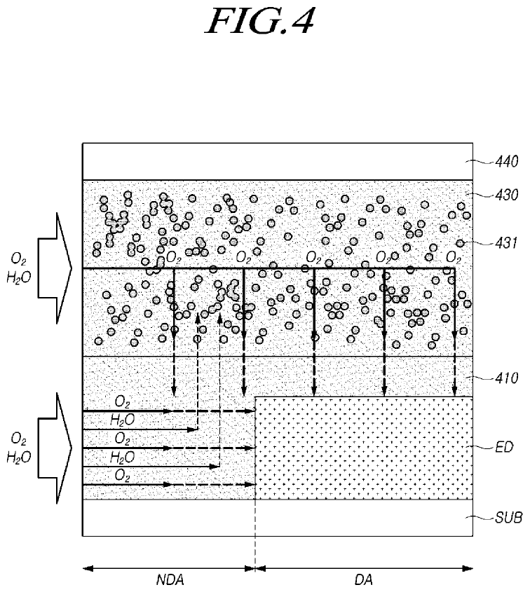

FIG. 4 is a cross-sectional view of a display device according to a comparative example of the present disclosure.

Referring to FIG. 4, the display device according to the comparative example of the present disclosure may include a substrate SUB, light-emitting elements ED disposed on the substrate SUB, and an encapsulation layer ENCAP disposed on the light-emitting elements ED.

The encapsulation layer ENCAP may include a first layer 410, a third layer 430 positioned on the first layer 410, and an encapsulation substrate 440. The third layer 430 may include a hygroscopic getter 431.

Moisture and oxygen may penetrate into the display device through a non-display area NDA. Moisture and oxygen may penetrate into a side surface of the light-emitting element ED through the first layer 410 or may penetrate into an upper portion of the light-emitting element ED through the third layer 430.

Moisture penetrating into the side surface of the light-emitting element ED through the first layer 410 may be absorbed by the hygroscopic getter 431 positioned in the third layer 430. In addition, moisture penetrating into the upper portion of the light-emitting element ED through the third layer 430 may be absorbed by the hygroscopic getter 431 positioned in the third layer 430. However, in the display device according to the comparative example, it is difficult to block oxygen penetrating into the upper portion of the light-emitting element ED through the third layer 430 and it is also difficult to block oxygen penetrating into the side surface of the light-emitting element ED through the first layer 410. In particular, oxygen penetrating into the side surface of the light-emitting element ED is handled only by a method of delaying the introduction of oxygen by widening the non-display area NDA. Accordingly, in the display device according to the comparative example, since the non-display area NDA is widened in order to delay a time at which the performance of the light-emitting element ED is degraded due to external oxygen, there is a problem in that a bezel area is widened.

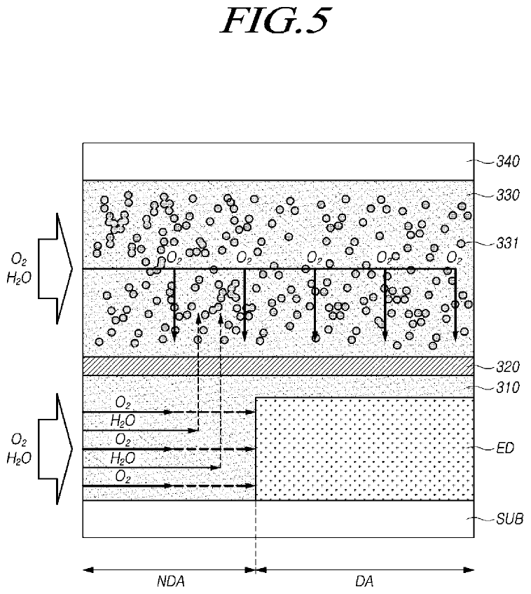

FIG. 5 is a cross-sectional view of a display device according to aspects of the present disclosure.

Referring to FIG. 5, the display device may include a second layer 320 unlike the display device according to the comparative example. Since the second layer 320 includes the compound represented by Formula 1, the second layer 320 may have a property of blocking oxygen as well as a property of transmitting moisture. Accordingly, the second layer 320 may allow moisture introduced from a non-display area NDA of the display device to pass therethrough such that the moisture is absorbed by a getter positioned in a third layer 330. In addition, since the second layer 320 has the property of blocking oxygen, the second layer 320 may block oxygen introduced into an upper portion of a light-emitting element ED through the third layer 330 from reaching the light-emitting element ED.

Accordingly, since a display device according to aspects of the present disclosure includes a second layer 320, which transmits moisture and blocks oxygen, between a first layer 310 and a third layer 330 including a hygroscopic getter, it is possible to considerably reduce an amount of moisture and oxygen penetrating into a light-emitting element ED. Accordingly, since a non-display area NDA does not need to be as wide as that of the comparative example so as to delay oxygen permeation, the display device according to aspects may have a small bezel area.

The above-described aspects of the present disclosure will be briefly described below.

A display device according to aspects of the present disclosure may include a substrate SUB, a light-emitting element ED disposed on the substrate SUB, and an encapsulation layer ENCAP disposed on the light-emitting element ED.

The encapsulation layer ENCAP may include a first layer, a second layer disposed on the first layer, and a third layer disposed on the second layer.

The first layer may include a first polymer. The second layer may include a compound represented by Formula 1 below. The third layer may include a second polymer and a hygroscopic getter.

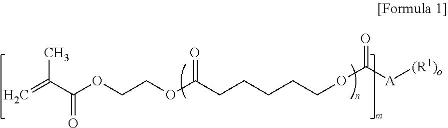

In Formula 1, A is a C₁-C₁₀ alkyl group or a C₆-C₆₀ aryl group. n is an integer from 1 to 100. m is an integer from 1 to 6. o is an integer greater than or equal to 1. R¹ is a hydroxyl group.

The first layer may have a thickness of 5 μm to 20 μm, the second layer may have a thickness of 1 μm to 30 μm, and the third layer may have a thickness of 10 μm to 80 μm.

The hygroscopic getter may include CaO.

The first polymer may be polyisobutylene.

The second polymer may be polyisobutylene.

The first polymer may have a weight average molecular weight of 200,000 to 800,000.

The second polymer may have a weight average molecular weight of 200,000 to 800,000.

The first polymer and the second polymer may be substantially the same polymer.

The first layer, the second layer, and the third layer may be in direct contact with each other.

The compound represented by Formula 1 may be represented by any one of Formulas 2 to 7 below.

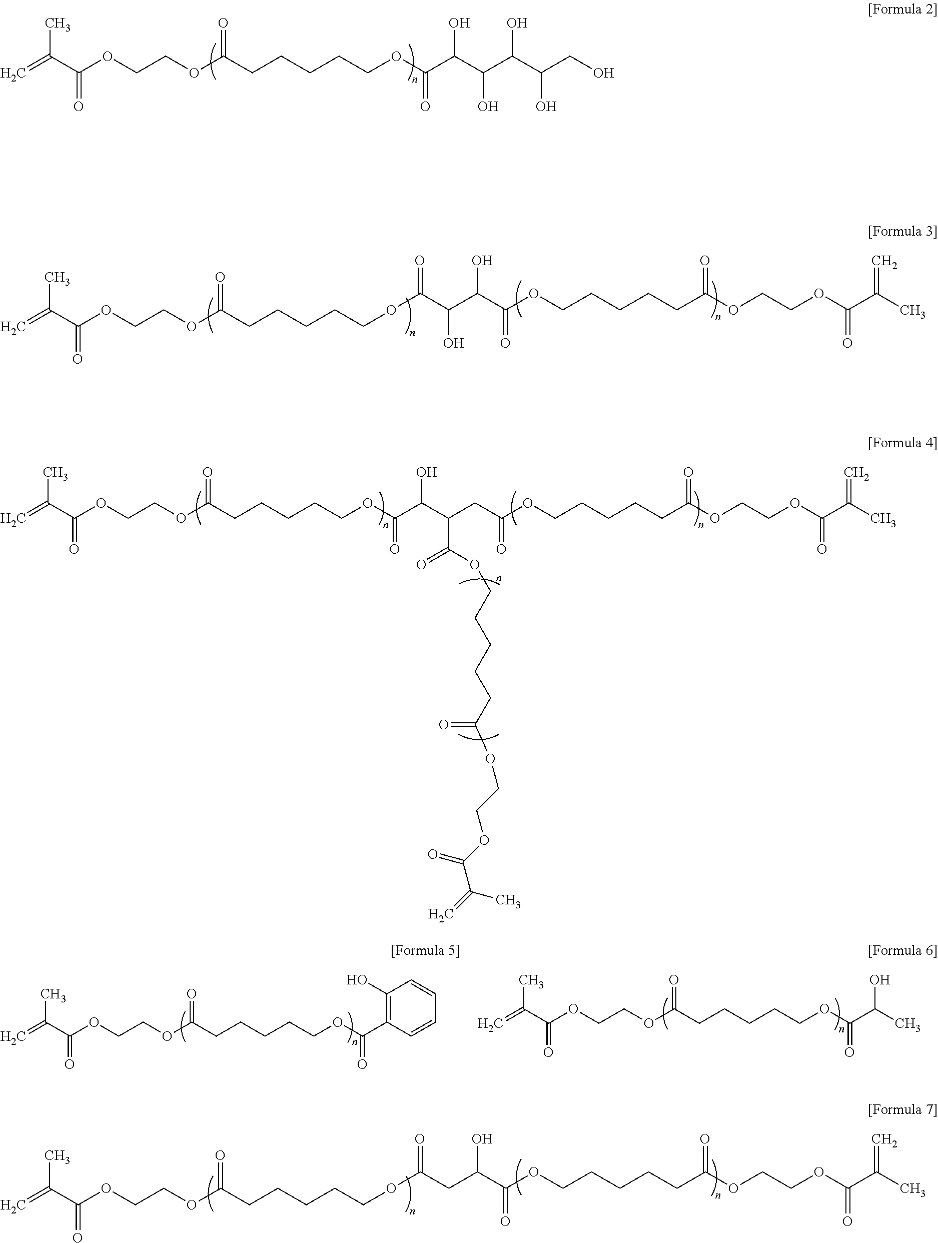

In Formulas 1 to 7, n is an integer from 1 to 100.

The compound represented by Formula 1 may have a weight average molecular weight of 3,000 to 30,000.

Hereinafter, an example of manufacturing an encapsulation layer of a display device according to aspects of the present disclosure will be described in detail through Examples, but aspects of the present disclosure are not limited to the following Examples.

The encapsulation layer might further include an encapsulation substrate on the third layer.

The substrate might include a display area and a non-display area, the light-emitting element might positioned in the display area.

In the non-display area, the first layer might extend to a side of the light-emitting element, and the second layer and the third layer might extend above the light-emitting element.

[Manufacturing Example of Encapsulation Layer Sample]

Manufacturing Example of Third Layer

100 g of a getter dispersion obtained by dispersing CaO (with an average particle size of 3 μm) in toluene at 50 wt %, 50 g of polyisobutylene (with a molecular weight of 400,000), and 200 g of a solution obtained by dissolving 50 g of an adhesive agent (SU130 manufactured by Kolon Industries) in toluene at 50 wt % were mixed and stirred for 3 hours in a nitrogen atmosphere. After the stirring was ended, 5 g of tricyclodecane dimethanol diacrylate (M262) and 2.5 g of 2,4,6-trimethylbenzoyl-diphenyl phosphine oxide (TPO) as a photoinitiator were added and stirred for 1 hour to prepare a third layer solution. After wet coating with and drying the prepared solution were performed, a film having a thickness of 40 μm was manufactured.

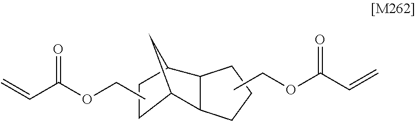

Manufacturing Example of First Layer

A film having a thickness of 10 μm was manufactured in the same manner as in Manufacturing Example of the third layer except that a CaO getter dispersion of Manufacturing Example of the third layer was not used.

Manufacturing Example of Second Layer

### Preparation Example 1

50 g of 2-hydroxyethyl methacrylate, 1,754 g of ε-caprolactone, 1.0 g of monobutyltin (IV) oxide as a catalyst, and 0.1 g of methoxyphenol as a polymerization inhibitor were introduced into a reactor equipped with a gas pipe, a thermometer, a condenser, and a stirrer, air in the reactor was substituted with nitrogen gas, and the introduced reactants were stirred at a temperature of 140° C. for 12 hours. It was confirmed through measurement of a solid content of a produced compound that 98% of the reactants reacted with each other. Such a reaction product had a weight average molecular weight of 5,900. 35.3 g of a gluconic acid was added to the reaction product and stirred at a temperature of 130° C. for 7 hours to terminate a reaction. A product obtained as described above is a compound represented by Formula 2 below. A reactive polymer with a weight average molecular weight of 6,300 was prepared as a waxy solid at a temperature of 25° C.

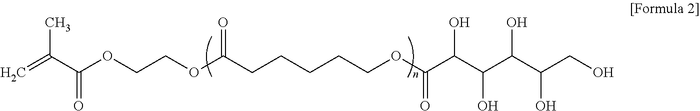

### Preparation Example 2

In Example 1, instead of 35.3 g of a gluconic acid of Preparation, 27.5 g of a tartaric acid was added and reacted. A prepared product is represented by Formula 3. As a produced compound, a reactive polymer having a weight average molecular weight of 12,500 was prepared.

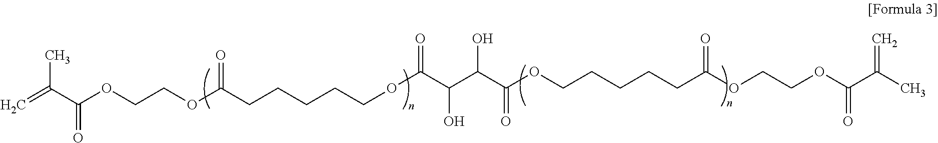

### Preparation Example 3

In Preparation Example 1, instead of 35.3 g of a gluconic acid, 29.0 g of a citric acid was added to a solvent, in which water and methanol were mixed in a 50:50 ratio, and reacted at a temperature of 75° C. A prepared product is represented by Formula 4. As a produced compound, a reactive polymer having a weight average molecular weight of 18,800 was prepared.

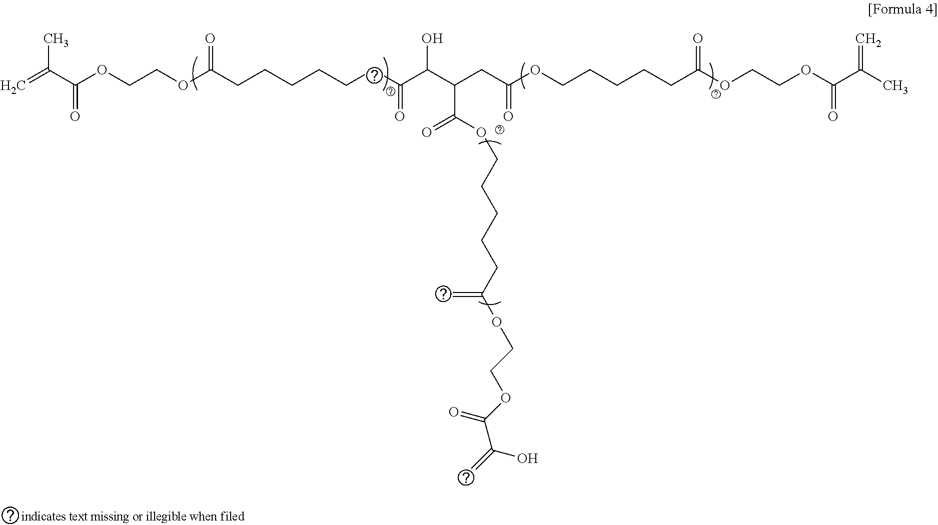

### Preparation Example 4

In Preparation Example 1, instead of 35.3 g of a gluconic acid, 25.0 g of a salicylic acid was added and reacted. A prepared product is represented by Formula 5. As an obtained compound, a reactive polymer having a weight average molecular weight of 5,200 was prepared.

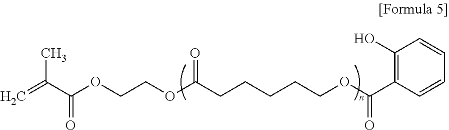

### Preparation Example 5

In Preparation Example 1, instead of 35.3 g of a gluconic acid, 24.0 g of a lactic acid was added and reacted. A prepared product is represented by Formula 6. As an obtained compound, a reactive polymer having a weight average molecular weight of 4,900 was prepared.

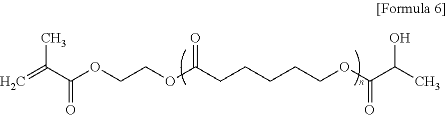

### Preparation Example 6

In Preparation Example 1, instead of 35.3 g of a gluconic acid, 28.4 g of a malic acid was added and reacted. A prepared product is represented by Formula 7. As a produced compound, a reactive polymer having a weight average molecular weight of 11,500 was prepared.

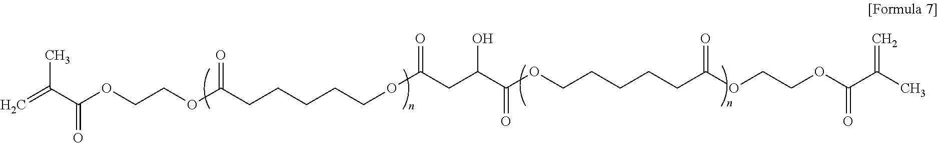

Manufacturing of Second Layer Film

Compositions of Examples were prepared by mixing reactants having a composition shown in Table 1 in a reactor equipped with a stirrer.

For example, in the case of Example 1, 250 g of a solution in which a binder (NPR1520 manufactured by Miwon Commercial Co., Ltd) was dissolved in propylene glycol monoethylether at 20 wt % was introduced into the reactor, 100 g of the reactive polymer of Formula 1 synthesized in Preparation Example 1 was added to reactive monomers, that is, 25 g of dipentaerythritol hexaacrylate (M600) and 25 g of dipropylene glycol diacrylate (M222) and was stirred at a temperature of 40° C. for 8 hours and confirmed to be transparent. Next, 600 g of propylene glycol monoethylether was added and stirred for 2 hours, and then undissolved materials and foreign materials were removed using a 0.1 μm filter to prepare a coating solution to be used for preparing a second layer.

In the remaining Examples, a coating solution of a second layer was prepared according to a composition of Table below as in the preparation of Example 1.

| | | Example | Example | Example | Example | Example | Example | Example | Comparative | Comparative |
|---|---|---|---|---|---|---|---|---|---|---|
| | | 1 | 2 | 3 | 4 | 5 | 6 | 7 | Example 1 | Example 2 |
| Binder | Benzyl | 5 | 5 | 5 | 5 | 5 | 5 | 5 | — | 5 |
| | methacylate | | | | | | | | | |
| | (NPR1520 | | | | | | | | | |
| | manufactured by | | | | | | | | | |
| | Miwon | | | | | | | | | |
| | Commercial Co., | | | | | | | | | |
| | Ltd) | | | | | | | | | |
| Monomer | DPHA (M600 | 2.5 | 2.5 | 2.5 | 2.5 | 2.5 | 2.5 | 2.5 | — | 2.5 |
| | manufactured by | | | | | | | | | |
| | Miwon | | | | | | | | | |
| | Commercial Co., | | | | | | | | | |
| | Ltd) | | | | | | | | | |
| | Dipropylene | 2.5 | 2.5 | 2.5 | 2.5 | 2.5 | 2.5 | 2.5 | — | 2.5 |
| | glycol diacrylate | | | | | | | | | |
| | (M222 | | | | | | | | | |
| | manufactured by | | | | | | | | | |
| | Miwon | | | | | | | | | |
| | Commercial Co., | | | | | | | | | |
| | Ltd) | | | | | | | | | |
| | Formual 2 | 10 | — | — | — | 5 | — | — | — | |
| | Formual 3 | — | 10 | | | 5 | — | — | — | |
| | Formual 4 | — | | 10 | | — | — | — | — | |
| | Formual 5 | — | | | 10 | — | — | — | — | |
| | Formual 6 | — | — | — | — | — | 10 | — | — | |
| | Formual 7 | — | — | — | — | — | | 10 | — | |
| Solvent | Propylene glycol | 80 | 80 | 80 | 80 | 80 | 80 | 80 | — | 90 |
| | monoethylether | | | | | | | | | |

In Comparative Example 1, a second layer was not formed, and in Comparative Example 2, a second layer did not include the compound represented by Formula 1.

Manufacturing of Sample for Evaluating Encapsulation Performance

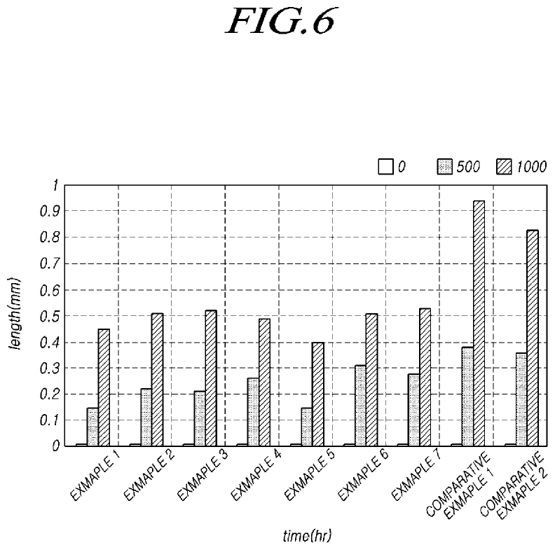

After an encapsulation film manufactured in Example was attached to an upper portion of an oxygen sensor of which a rear surface was attached to an upper portion of glass, and an oxygen permeation distance was measured at a temperature of 60° C. for 1,000 hours. By measuring a length of the oxygen sensor discolored compared with the initial state thereof, it was confirmed that the encapsulation film manufactured in Example had excellent performance in delaying oxygen permeation, and results are as shown in FIG. 6.

Referring to FIG. 6, it can be seen that Examples 1 to 7 show a shorter oxygen permeation length than that of Comparative Examples 1 and 2. Accordingly, it can be seen that Examples 1 to 7 include the second layer including the compound represented by Formula 1, thereby more effectively preventing the permeation of external oxygen.

The above description has been presented to enable any person skilled in the art to make and use the technical idea of the present disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present disclosure. The above description and the accompanying drawings provide an example of the technical idea of the present disclosure for illustrative purposes only. That is, the disclosed aspects are intended to illustrate the scope of the technical idea of the present disclosure. Thus, the scope of the present disclosure is not limited to the aspects shown, but is to be accorded the widest scope consistent with the claims. The scope of protection of the present disclosure should be construed based on the following claims, and all technical ideas within the scope of equivalents thereof should be construed as being included within the scope of the present disclosure.

What is claimed is:

1. A display device comprising:
a substrate;
a light-emitting element positioned on the substrate; and
an encapsulation layer positioned on the light-emitting element and comprising a first layer, a second layer positioned on the first layer, and a third layer positioned on the second layer,
wherein the first layer comprises a first polymer, the second layer comprises a compound represented by Formula 1 below, and the third layer comprises a second polymer and a hygroscopic getter, 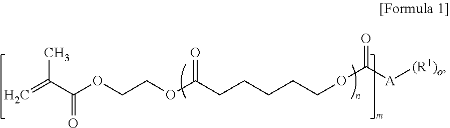
and
wherein, in Formula 1, A is a C₁-C₁₀ alkyl group or a C₆-C₆₀ aryl group, n is an integer from 1 to 100, m is an integer from 1 to 6, o is an integer greater than or equal to 1, and R¹ is a hydroxyl group.

2. The display device of claim 1, wherein the first layer has a thickness of 5 μm to 20 μm, the second layer has a thickness of 1 μm to 30 μm, and the third layer has a thickness of 10 μm to 80 μm.

3. The display device of claim 1, wherein the hygroscopic getter includes CaO.

4. The display device of claim 1, wherein the first polymer is polyisobutylene.

5. The display device of claim 1, wherein the second polymer is polyisobutylene.

6. The display device of claim 1, wherein the first polymer has a weight average molecular weight of 200,000 to 800,000.

7. The display device of claim 1, wherein the second polymer has a weight average molecular weight of 200,000 to 800,000.

8. The display device of claim 1, wherein the first polymer and the second polymer are substantially the same polymer.

9. The display device of claim 1, wherein the first layer, the second layer, and the third layer are in direct contact with one another.

10. The display device of claim 1, wherein the compound represented by Formula 1 is represented by any one of Formulas 2 to 7: 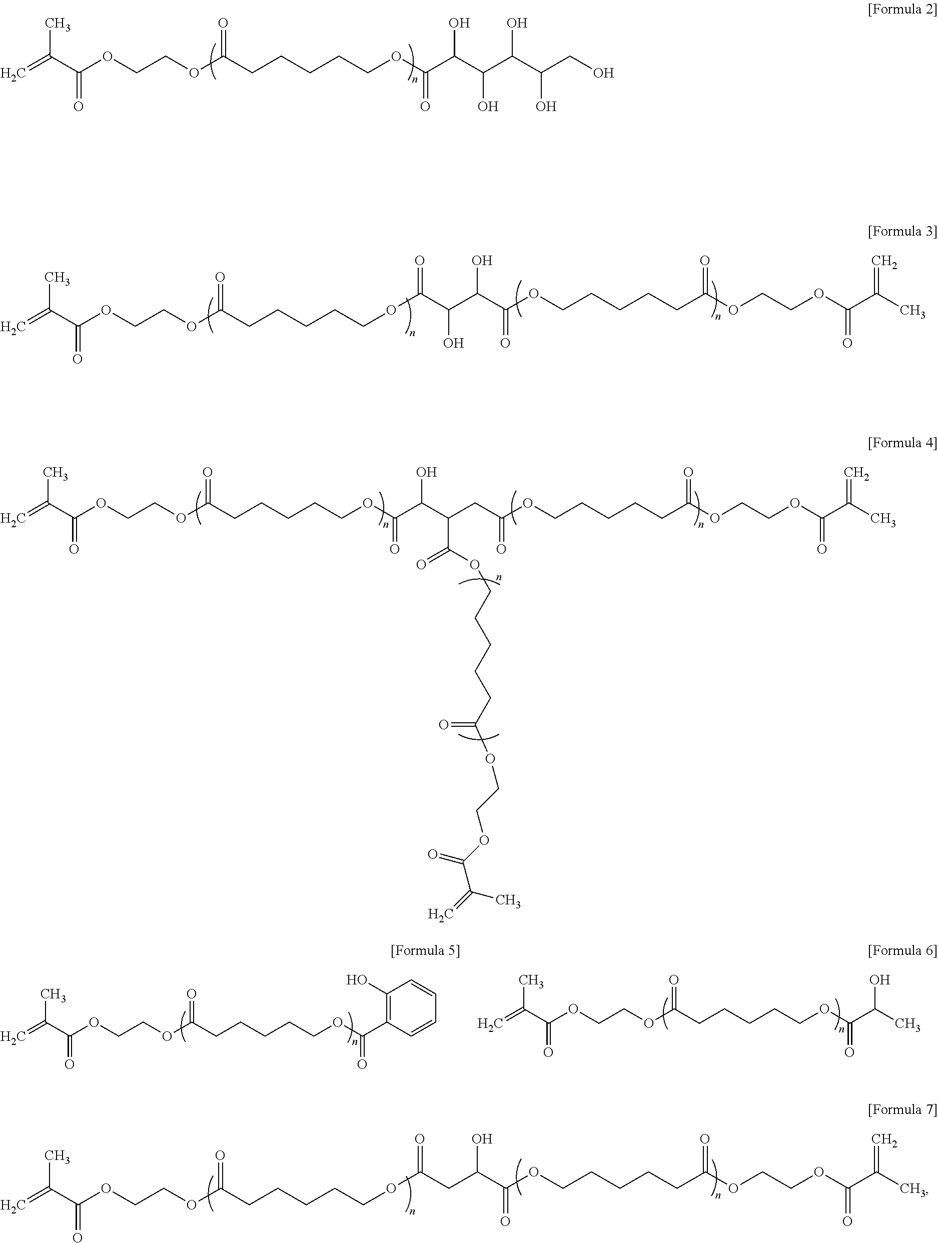
wherein, in Formula 1 to Formula 7, n is an integer from 1 to 100.

11. The display device of claim 1, wherein the compound represented by Formula 1 has a weight average molecular weight of 3,000 to 30,000.

12. The display device of claim 1, wherein the encapsulation layer further includes an encapsulation substrate on the third layer.

13. The display device of claim 1, wherein the substrate includes a display area and a non-display area, the light-emitting element is positioned in the display area.

14. The display device of claim 13, wherein, in the non-display area, the first layer extends to a side of the light-emitting element, and the second layer and the third layer extend above the light-emitting element.
